(19) United States
(12) Patent Application Publication
(10) Pub. No.: US 2018/0145130 A1
(43) Pub. Date: May 24, 2018

(54) IGBT WITH IMPROVED REVERSE BLOCKING CAPABILITY

(71) Applicant: Littelfuse, Inc., Chicago, IL (US)

(72) Inventors: Filip Kudrna, Roznov pod Radhostem (CZ); Roman Malousek, Frenstat p. R. (CZ); Justin Michael Yerger, West Warwick, RI (US)

(73) Assignee: Littelfuse, Inc., Chicago, IL (US)

(21) Appl. No.: 15/641,894

(22) Filed: Jul. 5, 2017

Related U.S. Application Data
(60) Provisional application No. 62/337,764, filed on May 17, 2016.

(51) Int. Cl. H01L 29/06; H01L 29/739; H01L 29/66; H01L 29/78

(52) U.S. Cl. CPC H01L 29/0611; H01L 29/7393; H01L 29/7802; H01L 29/66712; H01L 29/66333

(57) ABSTRACT

An insulated gate bipolar transistor (IGBT) device. The IGBT may include a substrate layer, the substrate layer comprising a p-type dopant, a first epitaxial layer, disposed on the substrate layer, the first epitaxial layer comprising an N-type dopant having a first concentration. The IGBT may also include a second epitaxial layer, disposed on the first epitaxial layer, the second epitaxial layer comprising an N-type dopant having a second concentration, the second concentration being greater than the first concentration. The IGBT may further include a third epitaxial layer, disposed on the second epitaxial layer, the third epitaxial layer comprising an N-type dopant having a third concentration, the third concentration being less than the first concentration.

### RELATED APPLICATIONS

This Application claims priority to U.S. Provisional Patent Application No. 62/337,764, entitled REVERSE BLOCKING IN IGNITION IGBTS, filed May 17, 2016, and incorporated by reference herein in its entirety.

### BACKGROUND

### Field

Embodiments relate to the field of semiconductor devices, and more particularly to an insulated gate bipolar transistor device.

### Discussion of Related Art

An insulated gate bipolar transistor (IGBT) device is a semiconductor device having four alternating layers (P-N-P-N) that are controlled by a metal-oxide-semiconductor (MOS) gate structure. As such, an IGBT may be considered as a hybrid device that has the output switching and conduction characteristics of a bipolar transistor, while being is voltage-controlled as in a metal oxide semiconductor field effect transistor (MOSFET). In particular, an IGBT cell may be constructed similarly to an n-channel vertical power MOSFET (NMOS portion) where the n⁺ drain is replaced with a p⁺ substrate layer, thus forming a vertical PNP bipolar junction transistor.

Specifically designed IGBTs with a clamping structure are particularly suitable as power switches in automotive ignition systems. In this regard, a high self-clamped inductive switching (SCIS) energy capability is useful device feature for IGBTs used in automotive ignition applications. Additionally, a low value of the collector-emitter ON voltage (VCEoN) is useful, while a high value of breakdown voltage, such as collector-emitter breakdown voltage, gate short-circuited to emitter, reverse condition (BV_{CESR}) is also useful. However, current technologies may not adequately meet all these requirements. For example, improving certain device parameters tends to degrade BV_{CESR}. In addition, higher BV_{CESR} is useful for applications involving 24V and 48V platforms for trucks and hybrids, and future car 48V networks.

With respect to these and other considerations, the present disclosure is provided.

### SUMMARY

In one embodiment, an insulated gate bipolar transistor (IGBT) device is provided. The IGBT may include a substrate layer, the substrate layer comprising a p-type dopant, as well as a first epitaxial layer, disposed on the substrate layer, the first epitaxial layer comprising an N-type dopant having a first concentration. The IGBT may also include a second epitaxial layer, disposed on the first epitaxial layer, the second epitaxial layer comprising an N-type dopant having a second concentration, the second concentration being greater than the first concentration. The IGBT may further include a third epitaxial layer, disposed on the second epitaxial layer, the third epitaxial layer comprising an N-type dopant having a third concentration, the third concentration being less than the first concentration.

In another embodiment, an insulated gate bipolar transistor (IGBT) device may include a semiconductor substrate, an emitter region, the emitter region disposed on a first side of the semiconductor substrate, and a substrate layer, the substrate layer disposed on a second side of the semiconductor substrate, opposite the first side, where the substrate layer comprises a p-type dopant. The IGBT device may include a drift layer, the drift layer comprising an N-type dopant and being disposed between the emitter region and the substrate layer, and a buffer layer, disposed on the substrate layer, the buffer layer comprising an N-type dopant, wherein the buffer layer comprises a graded dopant profile, wherein a dopant concentration of the buffer layer increases with increasing distance from the substrate layer.

In another embodiment, a method of forming an insulated gate bipolar transistor (IGBT) device may include providing a substrate layer, the substrate layer comprising a P-type dopant, and forming a first epitaxial layer on the substrate layer, the first epitaxial layer comprising an N-type dopant having a first concentration. The method may further include forming a second epitaxial layer, disposed on the first epitaxial layer, the second epitaxial layer comprising an N-type dopant having a second concentration, the second concentration being greater than the first concentration. The method may also include forming a third epitaxial layer, disposed on the second epitaxial layer, the third epitaxial layer comprising an N-type dopant having a third concentration, the third concentration being less than the first concentration.

### BRIEF DESCRIPTION OF THE DRAWINGS

FIG. 1 shows a schematic cross-section of an IGBT 100 according to embodiments of the disclosure;

FIG. 2 shows a spreading resistance profile (SRP) of one embodiment of the present disclosure;

FIG. 3, illustrates V_{CEON} characteristics for several exemplary embodiments of the present disclosure;

FIG. 4 illustrates V_{CEON} characteristics for several additional exemplary embodiments of the present disclosure;

FIG. 5 shows BV_{CESR} characteristics for several exemplary embodiments; and

FIG. 6 shows BV_{CESR} characteristics for several additional exemplary embodiments.

### DESCRIPTION OF EMBODIMENTS

The present embodiments will now be described more fully hereinafter with reference to the accompanying drawings, in which various embodiments are shown. The embodiments may be embodied in many different forms and are not to be construed as limited to the embodiments set forth herein. These embodiments are provided so that this disclosure will be thorough and complete, and will fully convey the scope of the embodiments to those skilled in the art. In the drawings, like numbers refer to like elements throughout.

In the following description and/or claims, the terms “on,” “overlying,” “disposed on” and “over” may be used in the following description and claims. “On,” “overlying,” “disposed on” and “over” may be used to indicate when two or more elements are in direct physical contact with one another. The terms “on,”, “overlying,” “disposed on,” and over, may also mean when two or more elements are not in direct contact with one another. For example, “over” may mean when one element is above another element and not in contact with another element, and may have another element or elements in between the two elements. Furthermore, the term “and/or” may mean “and”, it may mean “or”, it may mean “exclusive-or”, may mean “one”, may mean “some, not all”, may mean “neither”, and/or it may mean “both.” The scope of claimed subject matter is not limited in this respect.

The present embodiments are generally related to improved IGBT devices, or simply, “IGBTs.” Among the improvements afforded by the present embodiments are improved energy handling and robustness.

In various embodiments, ignition IGBTs are designed with improved reverse blocking capability. These IGBTs may have one or more of the following characteristics: high SCIS robustness, low V_{CEON}, or high BV_{CESR}. Some embodiments of an ignition IGBT may improve protection capabilities by maintaining acceptable values for all three characteristics. The epitaxial layer stack structure that forms a portion of an IGBT may be made to withstand reverse voltage while having an SCIS robustness and V_{CEON} similar to other IGBTs.

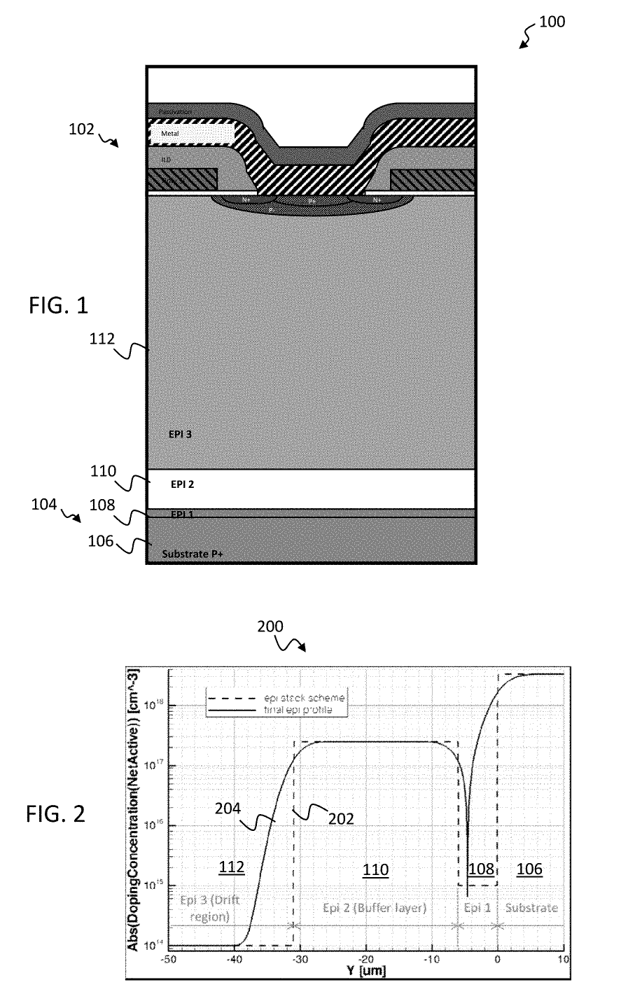

Referring now to FIG. 1, a schematic cross-section of an IGBT 100 according to embodiments of the disclosure is illustrated. The IGBT 100 may be formed in a known semiconductor substrate, such as silicon. The IGBT 100 may include an emitter region 102, arranged generally according to known devices IGBT. For example, the emitter region may be arranged at or near one surface of a semiconductor substrate that forms the IGBT 100, the top surface in the illustration of FIG. 1. The IGBT 100 may include a collector region 104, where the collector region 104 is arranged on at or near an opposite surface to the emitter region 102, as shown. The collector region 104 may include a collector electrode (not shown), as well as a substrate layer 106, formed in a region of the original substrate, shown as a P⁺ substrate.

In the embodiment illustrated in FIG. 1, to form the final semiconductor substrate of the IGBT, a series of epitaxial layers are disposed on the substrate layer 106. A first epitaxial layer 108 (also labeled EPI1) is disposed immediately adjacent and in contact with the substrate layer 106, that is, the P⁺ substrate. A second epitaxial layer 110 (also labeled as EPI2) is disposed on top of the first epitaxial layer 108 and not in contact with the substrate layer 106. A third epitaxial layer 112 (also labeled EPI3) is disposed on the second epitaxial layer 110 as shown. As detailed below, the third epitaxial layer 112 may act as a drift region and may be a lightly N-doped silicon layer, while the second epitaxial layer 110 may be formed as a more heavily N-doped buffer layer. The addition of the first epitaxial layer 108 may improve reverse blocking capability of the IGBT 100, as compared to known IGBTs.

Referring now to FIG. 2, a spreading resistance profile (SRP) of one embodiment of the present disclosure is shown. A curve 202 represents an initial design dopant profile for a portion of an IGBT 200, according to one embodiment. The IGBT 200 may include the various epitaxial layers and substrate (substrate layer), as represented in FIG. 1. The curve 202 plots net active dopant concentration as a function of position where the value of Y=0 um corresponds to the interface between the substrate and first epitaxial layer 108 and the substrate (substrate layer 106) for a designed structure. As shown, the substrate layer 106 (P^{t}) is designed with a concentration of approximately 3×10¹⁹/cm³ P-type dopant, while the first epitaxial layer is designed with a dopant concentration of 1×10¹⁵/cm³ (N-type) dopant, which concentration may represent an average dopant concentration. The second epitaxial layer 110 is designed with a dopant concentration of approximately 2.5×10¹⁷/cm³ N-type dopant, while the third epitaxial layer 112, forming the drift region, is designed with an N-type dopant concentration of approximately 1×10¹⁴/cm³.

In this exemplary embodiment, the third epitaxial layer 112 may extend to a thickness of many tens of micrometers (to the left in the figure) as in known IGBTs, while just an initial portion near the interface with the epitaxial layer 110 is shown. In this embodiment, the designed thickness of the second epitaxial layer 110 may be approximately 25 micrometers, while the designed thickness of the first epitaxial layer 108 is approximately 6 micrometers. The embodiments are not limited in this context.

The curve 204 represents the experimentally measured net active dopant concentration, after formation of the various epitaxial layers. The net active dopant concentration is directly obtained from spreading resistance measurements, again shown as a function of position with respect to the interface between the substrate and first epitaxial layer 108. With respect to some known IGBTs, the structure of IGBT 200 may have a thicker and more highly doped buffer layer, that is, first epitaxial layer 108. In addition, unlike known IGBTs, the IGBT 200 includes the additional epitaxial layer, first epitaxial layer 108, whose dopant concentration is designed at a lower level than the second epitaxial layer 110. The use of an additional epitaxial layer having a relatively lower dopant concentration may improve reverse blocking capability of the IGBT 200 compared to known IGBTs. The first epitaxial layer 108 may be overcompensated by out-diffusion from a highly doped substrate (substrate layer 106 and from the second epitaxial layer 110. In particular, the presence of the first epitaxial layer 108 may make the PN junction formed with the substrate layer 106 less steep, which less-steep junction may increase the breakdown voltage.

Some, but not all, embodiments of the present disclosure may arrange the first epitaxial layer 108 (EPI1) layer equal to or smaller than 10 μm. A buffer layer (such as the second epitaxial layer 108) may, but need not, have a thickness equal to or smaller than 35 □m or 25 μm. A doping concentration of an EPI1 layer may be between 1×10¹⁴/cm³ to 2×10¹⁶/cm³. A doping concentration of a buffer layer may be between 1×101⁷/cm³ to 5×10¹⁷/cm³. An EPI1 layer may have a sheet resistance from 0.3 Ωcm to 44.5 Ωcm. A buffer layer (such as the second epitaxial layer 108) may have a sheet resistance from 0.033 Ωcm to 0.086 Ωcm. These characteristics are merely illustrative examples of some implementations of the present disclosure. Embodiments of the present disclosure may use different thicknesses, doping concentrations, or sheet resistances.

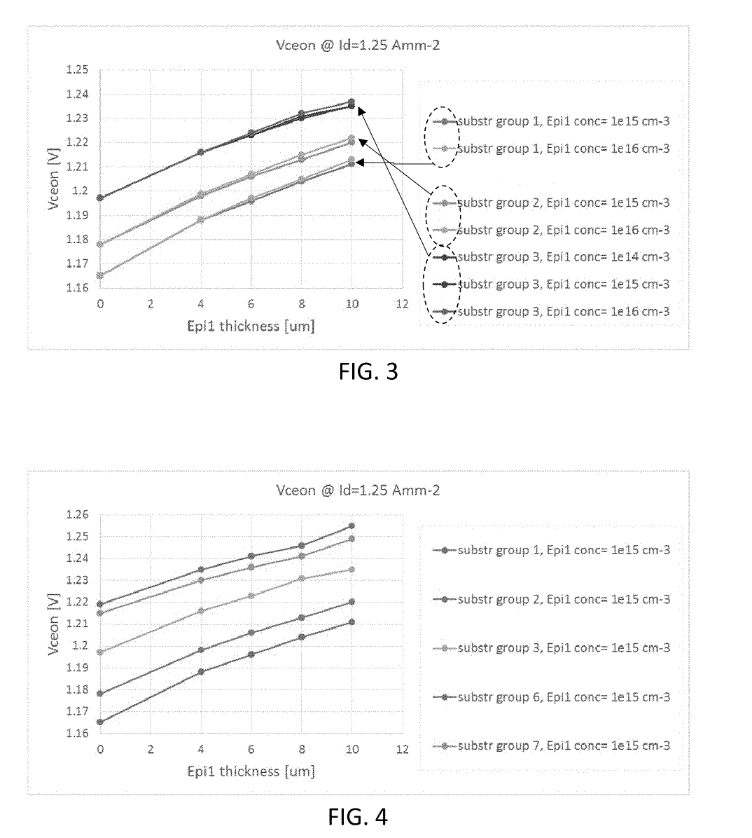

Referring now to FIG. 3, V_{CEON} characteristics are shown for several exemplary embodiments of the present disclosure. The values of V_{CEON} are shown as a function of the thickness of the EPI1 layer (first epitaxial layer 108), plotted on the abscissa. The values of V_{CEON} are also based on differing dopant concentration in the EPI1 layer, the EPI2 layer (second epitaxial layer 110) and in the EPI3 layer (third epitaxial layer 112). These latter differing values in EPI2 and EPI3 layers are not shown explicitly, but are reflected in the different groups. As shown, within a group, the concentration of dopant in the EPI1 layer does not have a pronounced effect on V_{CEON}, while there is a systematic difference in V_{CEON} between different groups for any given thickness of the EPI1 layer. Notably, for all different groups and different doping levels of the EPI1 layer, the increase in V_{CEON} with increasing thickness of the EPI1 layer is just 0.05 V or less up to at least 10 micrometers thickness, and in some groups the increase in V_{CEON} is as little as 0.03 V.

Referring now to FIG. 4, V_{CEON} characteristics are shown for several additional exemplary embodiments of the present disclosure. The data of FIG. 4 includes some of the data from FIG. 3, while additional groups are shown, reflecting differing dopant concentrations in the EPI2 layer and EPI3 layer, as discussed above. In FIG. 4, the concentration of dopant in the EPI1 layer is the same for all curves, 1×10¹⁵/cm³. Again, there is shown some systematic difference in V_{CEON} between different groups, while the same trends of FIG. 3 discussed above apply.

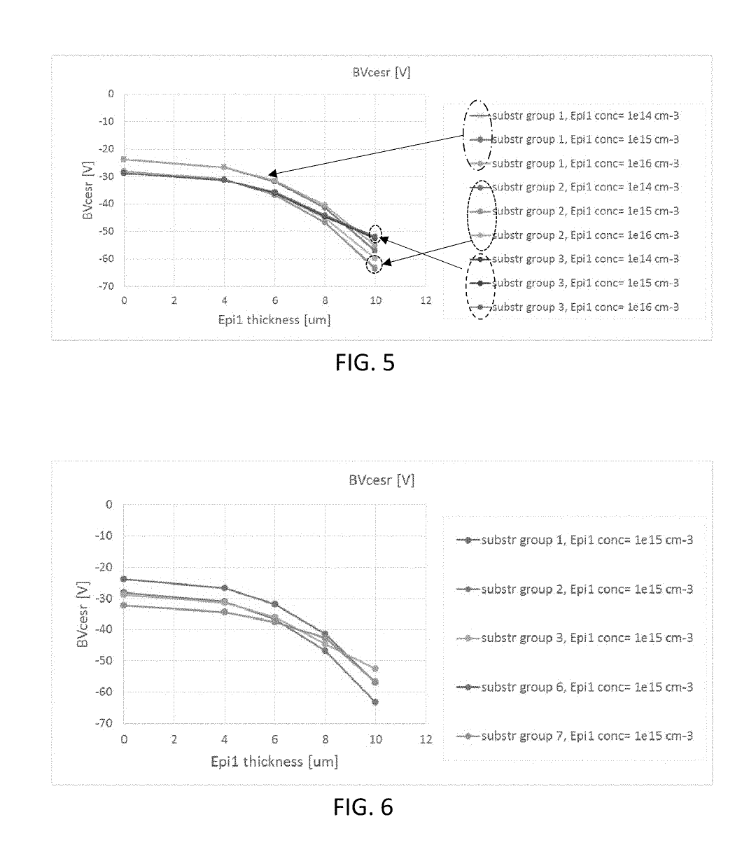

Referring now to FIG. 5, BV_{CESR} characteristics are shown for several exemplary embodiments, again shown as a function of EPI1 layer thickness on the abscissa, while differing concentrations in the EPI1 layer are reflected in the different curves as shown. Again, the different groups reflect different EPI2 concentration, and EPI3 concentration. As with the VCEoN data, a moderate dependence on the different group is observed, reflecting different EPI2 concentration and EPI3 concentration, while little dependence on dopant concentration in the EPI1 layer is seen, except a small dependence at 10 micrometers thickness of EPI1 layer. At 10 micrometers thickness, the samples having a concentration of 1×10^{16/}cm³ in the EPI1 layer have a lower absolute value of BV_{CESR} as compared to lower concentrations, up to several volts difference. Notably, a large increase (in absolute value) in BV_{CESR} occurs for all samples as a function of increasing thickness of EPI1 layer, approximately 30 V on average, from 0 micrometers to 10 micrometers in thickness.

Referring now to FIG. 6, BV_{CESR} characteristics are shown for several exemplary embodiments. Analogous to FIG. 4, the data of FIG. 6 includes some of the data from FIG. 5, while additional groups are shown, reflecting differing dopant concentrations in the EPI2 layer and EPI3 layer, as discussed above. In FIG. 6, the concentration of dopant in the EPI1 layer is the same for all curves, 1×10¹⁵/cm³. Again, there is shown some systematic difference in BV_{CESR} between different groups, while the same trends of FIG. 5 discussed above apply.

In summary, some embodiments may include an IGBT structure built on a stack of several layers. One layer may be a heavily doped P-type substrate (see substrate layer 106). Another layer (EPI2, see second epitaxial layer 110) may be a less heavily doped N-type buffer layer, relatively thick, such as 25 micrometers. A thinner buffer layer may also be used. Another layer (EPI3, see third epitaxial layer 112) may be a lowly doped N-type drift layer. The drift layer may hold a desired voltage. Another layer (EPI1, see first epitaxial layer 108) may be an extra lowly doped epitaxial layer, where the EPI1 layer is located between the substrate layer and the buffer layer. Accordingly, the EPI1 epitaxial layer may aid in maintaining SCIS robustness and VCEoN. In alternative embodiments, the EPI2 layer may exhibit a constant dopant profile or may exhibit a graded dopant profile where the dopant concentration changes as a function of depth. An example of a graded dopant concentration is where the concentration of N-type dopant increases from a minimum dopant concentration to a maximum dopant concentration with increasing distance from the substrate layer. In some embodiments, the EPI1 layer may be grown as part of the process for growing the EPI2 layer, thus avoiding additional processing operations.

Additional embodiments may include an IGBT structure built on a stack of several layers, including a heavily doped p-type substrate and a buffer layer (EPI2) having a graded concentration. The region of lower level dopant concentration of the buffer layer may improve reverse blocking capabilities. The region of higher level concentration of the buffer layer may serve to maintain a high SCIS robustness or low V_{CEON}. In other words, the embodiments where an IGBT includes a buffer layer (see second epitaxial layer 110) having a graded dopant concentration, the region of lower level dopant concentration of the buffer layer may act in place of the aforementioned first epitaxial layer 108, which layer may be omitted in these embodiments. In still other embodiments, a first epitaxial layer having a relatively lower N-type dopant concentration may be included together with a second epitaxial layer having the graded dopant concentration.

The graded dopant profile may be such, wherein a dopant concentration of the buffer layer increases with increasing distance from the substrate layer. In some embodiments, a buffer layer may include a first region and a second region wherein the first region comprises the graded dopant profile, and wherein the second region comprises a uniform dopant profile.

In addition, embodiments of the present disclosure may be non punch-through, punch-through, planar, or trench IGBTs.

Embodiments of the present disclosure may improve reverse blocking capability of devices. In some embodiments, SCIS or V_{CEON} may be at a similar level of devices that do not implement the present disclosure. Embodiments may not require additional processing steps and may not affect epitaxial layer cost.

Embodiments of the present disclosure may find applicability in, as just one example, automotive ignition IGBTs, or in other IGBT applications as well.

While the present embodiments have been disclosed with reference to certain embodiments, numerous modifications, alterations and changes to the described embodiments are possible without departing from the sphere and scope of the present disclosure, as defined in the appended claims. Accordingly, the present embodiments may not be limited to the described embodiments, but have the full scope defined by the language of the following claims, and equivalents thereof.

What is claimed is:

1. An insulated gate bipolar transistor (IGBT) device, comprising:
a substrate layer, the substrate layer comprising a p-type dopant;
a first epitaxial layer, disposed on the substrate layer, the first epitaxial layer comprising an N-type dopant having a first concentration;
a second epitaxial layer, disposed on the first epitaxial layer, the second epitaxial layer comprising an N-type dopant having a second concentration, the second concentration being greater than the first concentration; and
a third epitaxial layer, disposed on the second epitaxial layer, the third epitaxial layer comprising an N-type dopant having a third concentration, the third concentration being less than the first concentration.

2. The IGBT device of claim 1, wherein the first epitaxial layer comprises a thickness of 10 micrometers or less.

3. The IGBT device of claim 1, wherein the second epitaxial layer comprises a thickness of 25 micrometers or less.

4. The IGBT device of claim 1, wherein the first epitaxial layer comprises a dopant concentration of 1×10¹⁴/cm³ to 2×10¹⁶/cm³.

5. The IGBT device of claim 1, wherein the second epitaxial layer comprises a dopant concentration of 1×10¹⁷/cm³ to 5×10¹⁷/cm³.

6. The IGBT device of claim 1, wherein a sheet resistance of the first epitaxial layer ranges from 0.3 Ωcm to 44.5 Ωcm.

7. The IGBT device of claim 1, wherein a sheet resistance of the second epitaxial layer ranges from 0.33 Ωcm to 0.086 Ωcm.

8. An insulated gate bipolar transistor (IGBT) device, comprising:
a semiconductor substrate;
an emitter region, the emitter region disposed on a first side of the semiconductor substrate;
a substrate layer, the substrate layer disposed on a second side of the semiconductor substrate, opposite the first side, the substrate layer comprising a p-type dopant;
a drift layer, the drift layer comprising an N-type dopant and being disposed between the emitter region and the substrate layer; and
a buffer layer, disposed on the substrate layer, the buffer layer comprising an N-type dopant, wherein the buffer layer comprises a graded dopant profile, wherein a dopant concentration of the buffer layer increases with increasing distance from the substrate layer.

9. The IGBT device of claim 8, wherein the drift layer and the buffer layer are epitaxial layers.

10. The IGBT device of claim 8, wherein the buffer layer comprises a first average dopant concentration, wherein the drift layer comprises a second average dopant concentration, the second average dopant concentration being lower than the first average dopant concentration.

11. The IGBT device of claim 8, wherein the buffer layer comprises a thickness of 35 micrometers or less.

12. The IGBT device of claim 8, wherein the buffer layer comprises a minimum dopant concentration in a first region, the first region being adjacent and in contact with the substrate layer, and comprises a maximum dopant concentration in a second region, the second region not being in contact with the substrate layer,
wherein the minimum dopant concentration ranges from 1×10¹⁴/cm³ to 2×10¹⁶/cm³, and wherein the maximum dopant concentration ranges from 1×10¹⁷/cm³ to 5×10¹⁷/cm³.

13. The IGBT device of claim 12, wherein the first region comprises the graded dopant profile, and wherein the second region comprises a uniform dopant profile.

14. A method of forming an insulated gate bipolar transistor (IGBT) device, comprising:
providing a substrate layer, the substrate layer comprising a p-type dopant;
forming a first epitaxial layer on the substrate layer, the first epitaxial layer comprising an N-type dopant having a first concentration;
forming a second epitaxial layer, disposed on the first epitaxial layer, the second epitaxial layer comprising an N-type dopant having a second concentration, the second concentration being greater than the first concentration; and forming
a third epitaxial layer, disposed on the second epitaxial layer, the third epitaxial layer comprising an N-type dopant having a third concentration, the third concentration being less than the first concentration.

15. The method of claim 14, wherein the first epitaxial layer comprises a thickness of 10 micrometers or less.

16. The method of claim 14, wherein the second epitaxial layer comprises a thickness of 25 micrometers or less.

17. The method of claim 14, wherein the second epitaxial layer comprises a thickness of 35 micrometers or less.

18. The method of claim 14, wherein the first epitaxial layer comprises a dopant concentration of 1×10¹⁴/cm³ to 2×10¹⁶/cm³.

19. The method of claim 14, wherein the second epitaxial layer comprises a dopant concentration of 1×10¹⁷/cm³ to 5×10¹⁷/cm³.

20. The method of claim 14, wherein the first epitaxial layer and the second epitaxial layer comprise a buffer layer, wherein the second epitaxial layer comprises a uniform dopant profile, and wherein the first epitaxial layer comprises a graded dopant profile, wherein a dopant concentration of the first epitaxial layer increases with increasing distance from the substrate layer.
